(19) United States
(12) Patent Application Publication
(10) Pub. No.: US 2006/0145721 A1
(43) Pub. Date: Jul. 6, 2006

(54) Testing printed circuit boards of disk drives and servo track writers

(75) Inventor: Huang Ton-Churo, Cupertino, CA (US)

Correspondence Address: MICHAEL B. EINSCHLAG, ESQ., 25680 FERNHILL DRIVE, LOS ALTOS HILLS, CA, 94024, US

(73) Assignee: RioSpring, Inc., Milpitas, CA (US)

(21) Appl. No.: 11/026,229

(22) Filed: Dec. 31, 2004

(51) Int. Cl. G01R 31/26

(52) U.S. Cl. 324/765

(57) ABSTRACT

One embodiment of the present invention is method for testing a reading function of a printed circuit board of a disk drive or a servo track writer that includes: (a) providing a test pattern; (b) processing the test pattern to generate a digital signal series; (c) differentiating the digital signal series to provide a differentiated signal series; (d) applying the differentiated signal series as input to the printed circuit board; and (e) comparing an output from the printed circuit board with the test pattern.

### TECHNICAL FIELD OF THE INVENTION

One or more embodiments of the present invention relate to method and apparatus for testing disk drives, and more particularly, to method and apparatus for testing printed circuit boards (PCBs) of disk drives and PCBs of servo track writers (STWs).

### BACKGROUND OF THE INVENTION

In disk drive manufacturing, printed circuit boards (PCBs) of a disk drive have to be tested to ensure that such PCBs will, for example, correctly: (a) process data read from a disk; and (b) process data to be written onto the disk. In addition, PCBs of servo track writers (STWs) have to be tested to ensure that the STW PCBs will correctly process servo data read from/written onto a disk.

Conventionally, PCBs of large disk drives, such as 2.5″ and 3.5″ disk drives, are tested by: (a) adding test pads in the PCB layout design; and (b) using functional testers to probe the test pads. However, such a method of testing requires significant room on the PCBs and, therefore, it is not applicable for use with small disk drive PCBs which do not have sufficient space for test pads. Because of this, the prevalent method for testing small disk drive PCBs is to operate the disk drive to test the disk drive PCBs.

Although space is not a critical concern for small disk drive STW PCBs (i.e., test pads could be used for testing STW PCBs), conventional methods for testing STW PCBs entail measuring the performance of the STW PCBs by directly operating the STWs. This done because of test costs.

Problems encountered in directly operating disk drives to test disk drive PCBs and in directly operating STWs to test STW PCBs include: (a) loading/unloading testing heads for testing disk drive PCBs or STW PCBs is time consuming; (b) loading/unloading testing heads might cause damage and therefore might incur extra cost; (c) testing heads degrade after being used a number of times and therefore reduce test accuracy; and (d) replacing degraded testing heads incurs extra cost.

Testing based on simulation could help eliminate the above-identified problems. Although simulation methods have been used in large disk drives, the equipment required to generate appropriate signals for simulation is expensive.

In light of the above, there is a need in the art for method and apparatus for testing disk drive PCBs and/or STW PCBs that solve one or more of the above-identified problems.

### SUMMARY OF THE INVENTION

One or more embodiments of the present invention solve one or more of the above-identified problems. In particular, one embodiment of the present invention is a method for testing a reading function of a printed circuit board of a disk drive or a servo track writer that comprises: (a) providing a test pattern; (b) processing the test pattern to generate a digital signal series; (c) differentiating the digital signal series to provide a differentiated signal series; (d) applying the differentiated signal series as input to the printed circuit board; and (e) comparing an output from the printed circuit board with the test pattern. In addition, another embodiment of the present invention is a method for testing a writing function of a printed circuit board of a disk drive or a servo track writer that comprises: (a) providing a test pattern; (b) applying the test pattern as input to the printed circuit board to generate a digital signal series; (c) differentiating the digital signal series to provide a differentiated signal series; (d) processing the differentiated signal series; and (e) comparing an output from step (d) with the test pattern.

### BRIEF DESCRIPTION OF THE DRAWING

FIG. 1 shows an apparatus that is fabricated in accordance with one or more embodiments of the present invention for use in testing a reading function of printed circuit boards (PCBs) of disk drives or PCBs of servo track writer (STWs);

FIG. 2 is a flowchart of a method that is fabricated in accordance with one or more embodiments of the present invention (which, for example and without limitation, utilizes the apparatus shown in FIG. 1) for testing the reading function of the disk drive PCBs or the STW PCBs;

FIG. 3 shows an apparatus that is fabricated in accordance with one or more embodiments of the present invention for use in testing a writing function of PCBs of disk drives or PCBs of STWs;

FIG. 4 is a flowchart of a method that is fabricated in accordance with one or more embodiments of the present invention (which, for example and without limitation, utilizes the apparatus shown in FIG. 3) for testing the writing function of the disk drive PCBs or the STW PCBs;

FIG. 5 shows a portion of a digital signal series useful for testing an STW PCB in accordance with one or more embodiments of the present invention; and

FIG. 6 shows a differentiated signal series generated by differentiating the portion of the digital signal series shown in FIG. 5.

### DETAILED DESCRIPTION

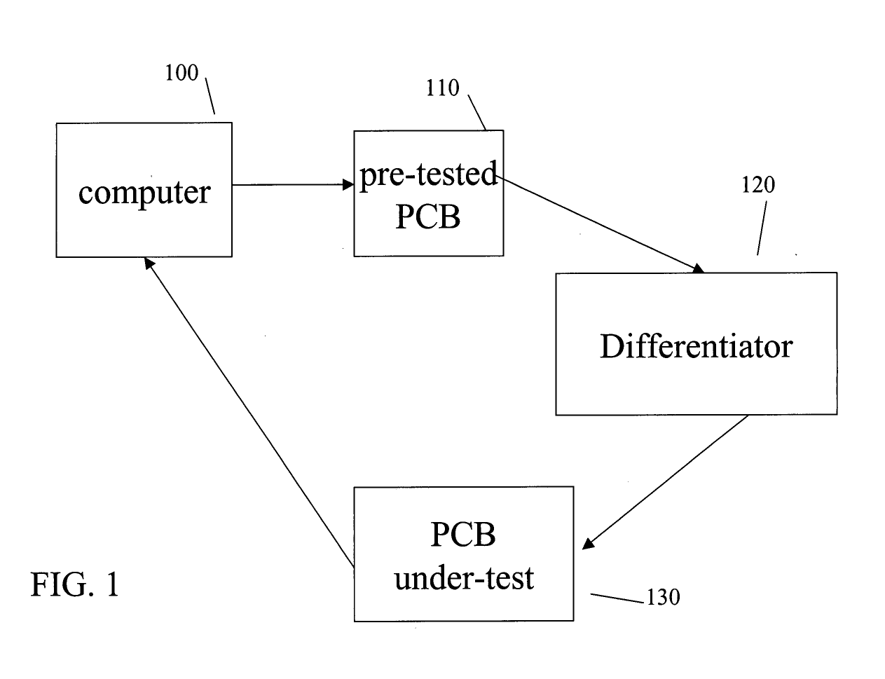

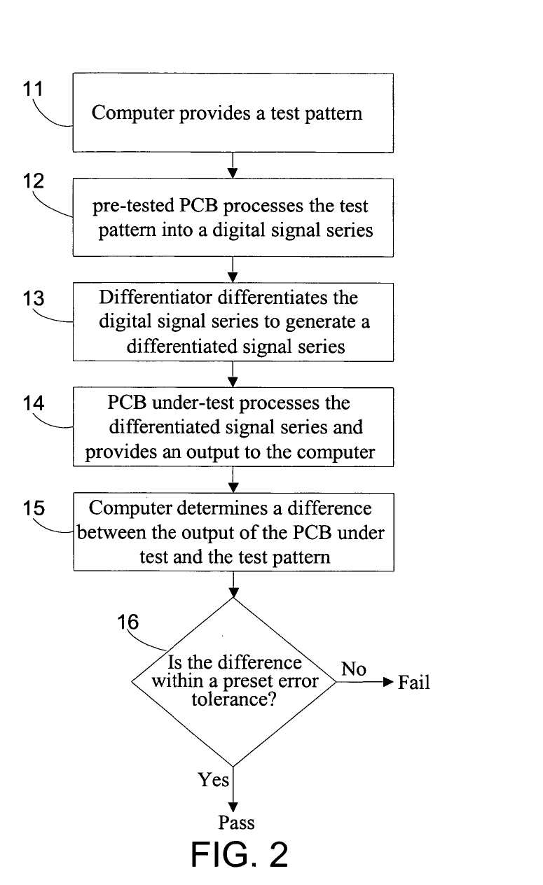

FIG. 1 shows an apparatus that is fabricated in accordance with one or more embodiments of the present invention for use in testing a reading function of printed circuit boards (PCBs) of disk drives or PCBs of servo track writer (STWs); and FIG. 2 is a flowchart of a method that is fabricated in accordance with one or more embodiments of the present invention (which, for example and without limitation, utilize the apparatus shown in FIG. 1) for testing the reading function of the disk drive PCBs or the STW PCBs.

The method starts with step 11 (shown in FIG. 2), at which computer 100 (shown in FIG. 1) outputs: (a) a test pattern (for example and without limitation, computer 100 acts as a pattern generator); and (b) optionally, and preferably, a command that will be intepreted by pre-tested PCB 110 as a command to process the test pattern (for example, and without limitation, a “write” command) into a digital signal series. As is known to those of ordinary skill in the art, PCBs of disk drives and PCBs of STWs typically include microcontrollers that operate under the direction of firmware, and that such firmware is typically downloaded, for example and without limitation, from a computer utilizing interfaces such as, for example and without limitation, standard, well known, ATA or IDE interfaces. In accordance with one or more embodiments of the present invention, pre-tested PCB 110 contains firmware that interprets the command, and causes pre-tested PCB 110 to process the test pattern in the manner described below. Such firmware may include standard firmware utilized by the PCB for standard writing functions. Further, such firmware may have been downloaded from computer 100 or from any other controller in accordance with any one of a number of methods that are well known to those of ordinary skill in the art. In accordance with one or more further embodiments of the present invention, firmware included in pre-tested PCB 110 may not require a separate command to cause it to process the test pattern, since the firmware may be limited to a specific status so that it will “automatically” process a test pattern presented to pre-tested PCB 110.

In accordance with one or more embodiments of the present invention, the test pattern may comprise, for example and without limitation, a series of 1s and 0s such as, for example and without limitation, a repeating series comprised of 110000—where a 0 is represented by a “low” voltage signal, and a 1 is represented by a “high” voltage signal. In particular, the “low” voltage signal may have any suitable value, and the “high” voltage signal may have any other suitable value such as a value that is higher than that of the “low” voltage signal. In a specific case, for example and without limitation, a suitable test pattern may be determined by the manufacturer of the disk drive. Then, control is transferred to step 12 (shown in FIG. 2). In addition, computer 100 may be any suitable computer such as, for example and without limitation, a PC or it may be any suitable circuitry that can carry out the functionality described herein, which functionality may be readily fabricated by one of ordinary skill in the art utilizing conventional components.

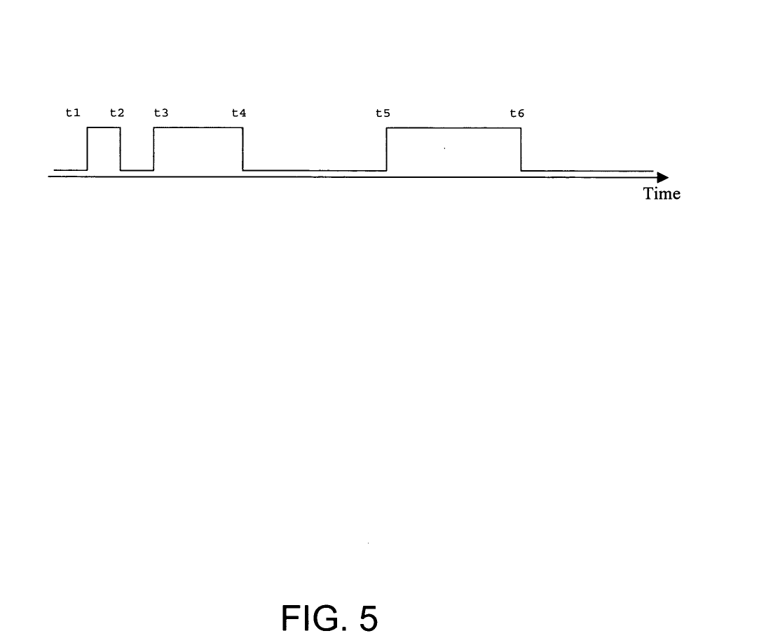

At step 12 (shown in FIG. 2), the test pattern and optionally, the command, are applied as input to pre-tested PCB 110 (shown in FIG. 1), and pre-tested PCB 110—in turn—generates a digital signal series by processing the test pattern (for example and without limitation, pre-tested PCB 110 acts as a signal processor that encodes the test pattern). There are many ways to process the test pattern that are well known to those of ordinary skill in the art such as, for example and without limitation by encoding the test pattern. For example, and without limitation, frequency modulation encoding (FM encoding) encodes every 1 into 11 and every 0 into 01, and the above described exemplary test pattern 110000 can be FM encoded into the following digital signal series: 111101010101. FIG. 5 shows a portion of a digital signal series (i.e., a pattern of 1s and 0s) useful for testing a certain type of STW PCB using the method described above in conjunction with FIG. 2 (other types of STW PCBs may be testing using other types of digital signal series). As shown in FIG. 5, the series comprises: (a) a 1 in a time interval beween t1 and t2 where t2−t1=200 nanoseconds; (b) a 0 in a time interval between t2 and t3 where t3−t2=200 nanoseconds; (c) a 1 in a time interval between t3 and t4 where t4−t3=600 nanoseconds; (d) a 0 in a time interval between t4 and t5 where t5−t4=1000 nanoseconds; (e) a 1 in a time interval between t5 and t6 where t6−t5=1000 nanoseconds; and (f) repeating 1s and 0s where the 1s and 0s are each 1000-nanosecond long. A pattern in the digital signal series (referred to as an index pattern) designates a start of the digital signal series, which index pattern consists of 1s and 0s in the interval from t1 to t4. The rest of the digital signal series includes 7099 periodic 1s and 0s where the 1 and 0s are 1000 nanoseconds, i.e., 1 microsecond, long. The 1s and 0s may be generated in pre-tested PCB 110 in accordance with any one of a number of methods that are well known to those of ordinary skill in the art using a clock (not shown) having a frequency of at least 20 megahertz (where a faster clock is preferred).

In accordance with one or more embodiments of the present invention, pre-tested PCB 110 processes the test pattern correctly. To ensure this, pre-tested PCB 110 can be pre-tested by: (a) installing it in a device, for example, and without limitation, an STW or a disk drive, as appropriate, and (b) measuring the performance of the device in accordance with any one of a number of methods that are well known to those of ordinary skill in the art. In accordance with one or more alternative embodiments of the present invention, a circuit such as, for example and without limitation, a field programmable gate array (FPGA) or a circuit designed utilizing conventional electronic components can be used in lieu of pre-tested PCB 110 for processing the test pattern. Then, control is transferred to step 13 (shown in FIG. 2).

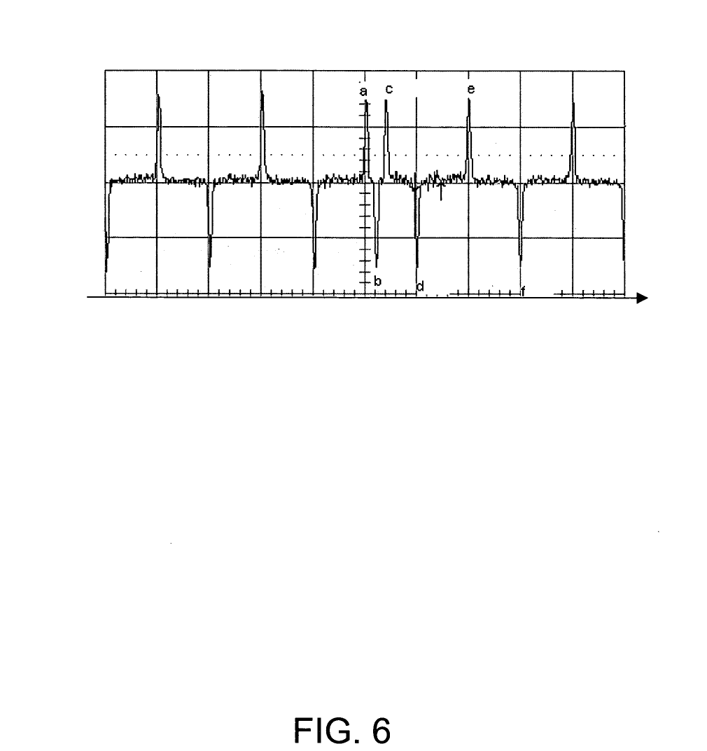

At step 13 (shown in FIG. 2), the digital signal series output from pre-tested PCB 110 (or FPGA 110 or electronic circuit 110) (shown in FIG. 1) is applied as input to Differentiator 120 to generate a differentiated signal series. For example and without limitation, for the exemplary digital signal series portion 111101010101 discussed above, the resulting differentiated signal series will consist of an up pulse at the beginning, and four clock periods later, alternate down pulses and up pulses in every two clock periods for eight clock periods. FIG. 6 shows a differentiated signal series generated by differentiating the portion of the digital signal series shown in FIG. 5. As shown in FIG. 6, the differentiated signal series comprises: (a) an up pulse at time a and a down pulse at time b where a time interval between time a and time b, i.e., b−a,=200 nanoseconds; (b) an up pulse at time c where a time interval between time b and time c, i.e., c−b,=200 nanoseconds; (c) a down pulse at time d where a time interval between time c and time d, i.e., d−c,=600 nanoseconds; (d) an up pulse at time e where a time interval between time d and time e, i.e., e−d,=1000 nanoseconds; (e) a down pulse at time f where a time interval between time e and time f, i.e., f−e,=1000 nanoseconds; and (f) repeating up pulses and down pulses at 1000-nanosecond intervals. A pattern formed by the pulses at time a, time b, time c and time d is an index pattern which corresponds to the pulses in the interval between t1 to t4 in FIG. 5. Thus, the differentiated signal series starts with the index pattern, and is followed by 7099 periodical up spikes and 7099 periodical down spikes such as those shown at time e and time f of FIG. 6. As a result, the differentiated signal series consists of 7101 up spikes and 7101 down spikes, and this signal may be repeated continuously. In accordance with one or more embodiments of the presernt invention, an up pulse is followed by a down pulse, and the total number of up pulses equals the total number of down pulses in the entire series. In addition, whenever an STW PCB is tested, the peak-to-peak amplitude of the differentiated signal series can be varied from about 100 millivolts to about 300 millivolts in accordance with any one of a number of methods that are well known to those of ordinary skill in the art including by use of an AD835 or AD834 multiplier. The differentiation can be carried out using, for example and without limitation, an RC differentiator circuit. Then, control is transferred to step 14 (shown in FIG. 2).

At step 14 (shown in FIG. 2), the differentiated signal series is applied as input to PCB under-test 130 (shown in FIG. 1), and PCB under-test 130 treats the differentiated signal series as if the differentiated signal series were received from a device (for example, a read/write head of a disk drive), and processes it accordingly. In accordance with one or more embodiments of the present invention, the differentiated signal series is applied to an analog input (for example and without limitation, RDX and RDY inputs) of PCB under-test 130, and in accordance with one or more embodiments of the present invention, PCB under-test 130 contains firmware that causes it to respond to the differentiated signal series as if the differentiated signal series had been generated as a result of a “read” from the device (preferably, such firmware is standard firmware utilized by the PCB for standard reading funtions). For example and without limitation, PCB under-test 130 acts as a signal processor that decodes the differentiated signal series. Further, such firmware may have been downloaded from computer 100 or from any other controller in accordance with any one of a number of methods that are well known to those of ordinary skill in the art. The processed signal is then applied as input to computer 100. Then, control is transferred to step 15 (shown in FIG. 2).

At step 15 (shown in FIG. 2), computer 100 (shown in FIG. 1) compares the output from PCB under-test 130 with the test pattern output from computer 100 (for example and without limitation, acts as a comparator). The comparison between the test pattern and the output from PCB under-test 130 can be performed in accordance with any one of a number of other methods that are well known to those of ordinary skill in the art. For example, the output from PCB under-test 130 may be converted to a string of bits (for example and without limitation, 1s and 0s), and the string may be compared to a string of bits representing the test pattern. Then, control is transferred to step 16 (shown in FIG. 2).

At step 16 (shown in FIG. 2), if differences between the output from PCB under-test 130 and the test pattern output from computer 100 are within preset error tolerances, then PCB under-test 130 passes the test; otherwise, PCB under-test 130 fails the test. In any case, computer 100 reports the results of the test, for example and without limitation, by printing the result on a printer, or by sending a message to another computer, a terminal, and so forth.

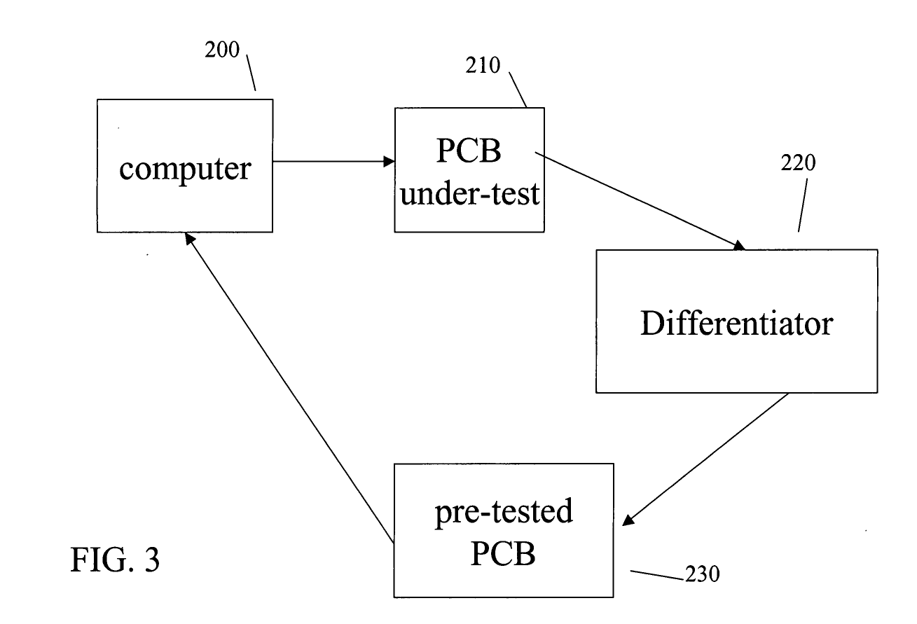

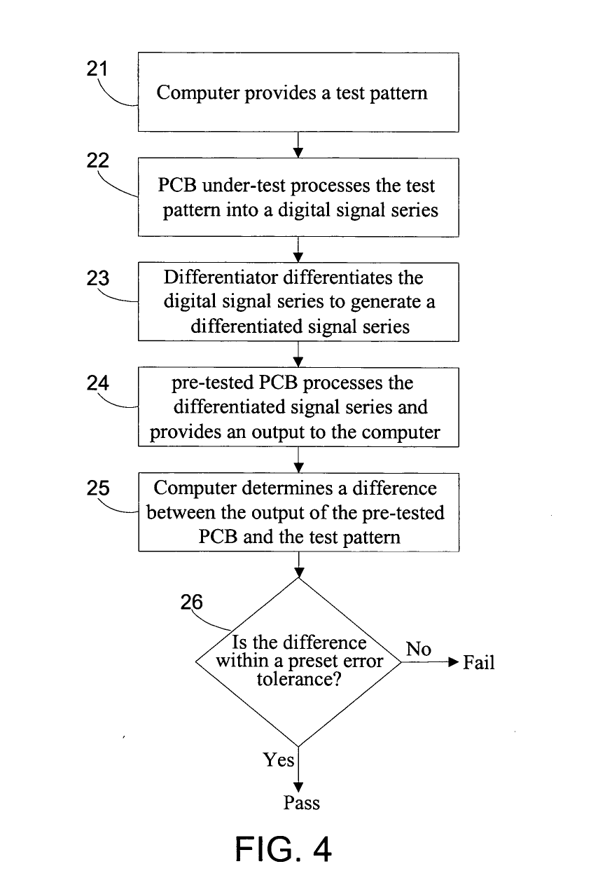

FIG. 3 shows an apparatus that is fabricated in accordance with one or more embodiments of the present invention for use in testing a writing function of PCBs of disk drives or PCBs of STWs; and FIG. 4 is a flowchart of a method that is fabricated in accordance with one or more embodiments of the present invention (which, for example and without limitation, utilize the apparatus shown in FIG. 3) for testing the writing function of the disk drive PCBs or the STW PCBs.

The method starts with step 21 (shown in FIG. 4), at which computer 200 (shown in FIG. 3) outputs: (a) a test pattern (for example and without limitation, computer 200 acts as a pattern generator); and (b) optionally, and preferably, a command that will be interpreted by PCB under-test 210 as a command to process the test pattern (for example, and without limitation, a “write” command) into a digital signal series. As is known to those of ordinary skill in the art, PCBs of disk drives and PCBs of STWs typically include microcontrollers that operate under the direction of firmware, and that such firmware is typically downloaded, for example and without limitation, from a computer utilizing interfaces such as, for example and without limitation, standard, well known, ATA or IDE interfaces. In accordance with one or more embodiments of the present invention, PCB under-test 210 contains firmware that interprets the command, and causes PCB under-test 210 to process the test pattern in the manner described below. Such firmware may include standard firmware utilized by the PCB for standard writing functions. Further, such firmware may have been downloaded from computer 200 or from any other controller in accordance with any one of a number of methods that are well known to those of ordinary skill in the art. In accordance with one or more further embodiments of the present invention, firmware included in PCB under-test 210 may not require a separate command to cause it to process the test pattern, since the firmware may be limited to a specific status so that it will “automatically” process a test pattern presented to PCB 210.

In accordance with one or more embodiments of the present invention, the test pattern may comprise, for example and without limitation, a series of 1s and 0s. In a specific case, for example and without limitation, a suitable test pattern may be determined by the manufacturer of the disk drive. Then, control is transferred to step 22 (shown in FIG. 4). In addition, computer 200 may be any suitable computer such as, for example and without limitation, a PC or it may be any suitable circuitry that can carry out the functionality described herein, which functionality may be readily fabricated by one of ordinary skill in the art utilizing conventional components.

At step 22 (shown in FIG. 4), the test pattern and optionally, and preferably, the command, are applied as input to PCB under-test 210 (shown in FIG. 3), and PCB under-test 210 in turn, processes the test pattern into a digital signal series (for example and without limitation, PCB under-test 210 acts as a signal processor that encodes the test pattern). Then, control is transferred to step 23 (shown in FIG. 4).

At step 23 (shown in FIG. 4), the digital signal series output from PCB under-test 210 is applied as input to Differentiator 220 (shown in FIG. 3) to generate a differentiated signal series. The differentiation can be carried out using, for example and without limitation, an RC differentiator circuit. Then, control is transferred to step 24 (shown in FIG. 4).

At step 24 (shown in FIG. 4), the differentiated signal series is applied as input to pre-tested PCB 230 (shown in FIG. 3), and pre-tested PCB 230 treats the differentiated signal series as if the differentiated signal series were received from a device (for example, a read/write head of a disk drive), and processes it accordingly. In accordance with one or more embodiments of the present invention, the differentiated signal series is applied to an analog input (for example and without limitation, RDX and RDY inputs) of pre-tested PCB 230, and in accordance with one or more embodiments of the present invention, pre-tested PCB 230 contains firmware that causes it to respond to the differentiated signal series as if the differentiated signal series had been generated as a result of a “read” from the device (preferably, such firmware is standard firmware utilized by the PCB for standard reading functions). Further, such firmware may have been downloaded from computer 200 or from any other controller in accordance with any one of a number of methods that are well known to those of ordinary skill in the art. In accordance with one or more embodiments of the present invention, pre-tested PCB 230 processes the differentiated signal series correctly to form a pattern (for example and without limitation, pre-tested PCB 230 acts as a signal processor that decodes the differentiated signal series). To ensure this, pre-tested PCB 230 can be pre-tested by: (a) installing it in a device, for example, and without limitation, an STW or a disk drive, as appropriate; and (b) measuring the performance of the device in accordance with any one of a number of methods that are well known to those of ordinary skill in the art. In accordance with one or more alternative embodiments of the present invention, a circuit such as, for example and without limitation, a circuit designed utilizing conventional electronic components can be used in lieu of pre-tested PCB 230 for processing the differentiated digital signal series. The output from pre-tested PCB 230 is then applied as input to computer 200. Then, control is transferred to step 25 (shown in FIG. 4).

At step 25 (shown in FIG. 4), computer 200 (shown in FIG. 3) compares the output from pre-tested PCB 230 with the test pattern output from computer 200 (for example and without limitation, acts as a comparator apparatus). The comparison between the test pattern and the output from pre-tested PCB 230 can be performed in accordance with any one of a number of other methods that are well known to those of ordinary skill in the art. For example, the output from pre-tested PCB 230 may be converted to a string of bits (for example and without limitation, 1s and 0s), and the string may be compared to a string of bits representing the test pattern. Then, control is transferred to step 26 (shown in FIG. 4).

At step 26 (shown in FIG. 4), if the differences between the output from pre-tested PCB 230 and the test pattern from computer 200 are within preset error tolerances, then PCB under-test 210 passes the test; otherwise, PCB under-test 210 fails the test. In any case, computer 100 reports the results of the test, for example and without limitation, by printing the result on a printer, or sending a message to another computer, a terminal, and so forth.

Advantageously in accordance with one or more embodiments of the present invention, a need to connect PCBs under test with testing heads is eliminated. As a result, inaccuracy and cost from degradation of testing heads and replacements thereof may be eliminated. In addition, without loading and unloading of testing heads, testing efficiency may be improved. Lastly, for embodiments using pre-tested PCBs, ease of development is ensured because there is no need to design and debug extra circuitry.

The embodiments of the present invention described above are exemplary. Many changes and modifications may be made to the disclosure recited above, while remaining within the scope of the invention. For example, although embodiments of the invention were shown with one PCB under-test, further embodiments may be fabricated utilizing a number of PCBs under-test at the same time. The scope of the invention should, therefore, be determined not with reference to the above description, but instead should be determined with reference to the appended claims along with their full scope of equivalents.

What is claimed is:

1. A method for testing a reading function of a printed circuit board of a disk drive or a servo track writer that comprises:
providing a test pattern;
processing the test pattern to generate a digital signal series;
differentiating the digital signal series to provide a differentiated signal series;
applying the differentiated signal series as input to the printed circuit board; and
comparing an output from the printed circuit board with the test pattern.

2. The method of claim 1 wherein the step of processing comprises utilizing a pre-tested printed circuit board for processing.

3. The method of claim 1 wherein the step of processing comprises utilizing a field programmable gate array for processing.

4. The method of claim 1 wherein the printed circuit board is a servo track writer printed circuit board.

5. The method of claim 1 wherein the printed circuit board is a printed circuit board of a disk drive.

6. The method of claim 1 wherein the digital signal comprises time intervals between up pulses of 200 nanoseconds, 600 nanoseconds, and 1000 nanoseconds.

7. The method of claim 1 wherein the digital signal is generated utilizing a clock with a frequency of at least 20 megahertz

8. The method of claim 1 wherein the step of differentiating comprises utilizing an RC differentiator.

9. The method of claim 1 wherein the differentiated signal has a peak-to-peak amplitude in a range of about 100 millivolts to about 300 millivolts.

10. The method of claim 1 wherein a peak-to-peak amplitude of the differentiated signal may be adjusted by utilizing an AD835 or AD834 multiplier.

11. A method for testing a writing function of a printed circuit board of a disk drive or a servo track writer that comprises:
providing a test pattern;
applying the test pattern as input to the printed circuit board to generate a digital signal series;
differentiating the digital signal series to provide a differentiated signal series;
processing the differentiated signal series; and
comparing processed output from the step of processing with the test pattern.

12. The method of claim 11 wherein the printed circuit board is a servo track writer printed circuit board.

13. The method of claim 11 wherein the printed circuit board is a printed circuit board of a disk drive.

14. The method of claim 11 wherein the step of differentiating comprises utilizing an RC differentiator.

15. The method of claim 11 wherein the differentiated signal has a peak-to-peak amplitude in a range of about 100 millivolts to about 300 millivolts.

16. The method of claim 11 wherein a peak-to-peak amplitude of the differentiated signal may be adjusted by utilizing an AD835 or AD834 multiplier.

17. An apparatus for testing a reading function of a printed circuit board of a disk drive or a servo track writer that comprises:
a pattern generator that generates a test pattern;
a signal processor that processes the test pattern to generate a digital signal series;
a differentiator that differentiates the digital signal series to provide a differentiated signal series as input to the printed circuit board; and
a comparator that compares an output from the printed circuit board with the test pattern.

18. The apparatus of claim 17 wherein the signal processor comprises a pre-tested printed circuit board.

19. The apparatus of claim 17 wherein the comparator comprises a computer.

20. An apparatus for testing a writing function of a printed circuit board of a disk drive or a servo track writer that comprises:
a pattern generator that generates a test pattern as input to the printed circuit board, in response to which, the printed circuit board generates a digital signal series;
a differentiator that differentiates the digital signal series to provide a differentiated signal series;
a signal processor that processes the differentiated signal series to provide an output; and
a comparator that compares the output from the signal processor with the test pattern.
